(19) United States
(12) Patent Application Publication
(10) Pub. No.: US 2013/0049007 A1
(43) Pub. Date: Feb. 28, 2013

(54) WIDE-BANDGAP SEMICONDUCTOR DEVICE

(71) Applicant: Hajime SASAKI, Tokyo (JP)

(72) Inventor: Hajime SASAKI, Tokyo (JP)

(73) Assignee: MITSUBISHI ELECTRIC CORPORATION, Tokyo (JP)

(21) Appl. No.: 13/437,086

(22) Filed: Apr. 2, 2012

(30) Foreign Application Priority Data
Aug. 29, 2011 (JP) 2011-186428

(51) Int. Cl. H01L 29/15

(52) U.S. Cl. 257/76; 257/E29.072

(57) ABSTRACT

A wide-bandgap semiconductor device includes: a semiconductor substrate made of a semiconductor material having a bandgap larger than 1.42 eV; a semiconductor layer on the semiconductor substrate and made of a semiconductor material having a bandgap larger than 1.42 eV; and an active region in the semiconductor layer and including a transistor, wherein the wide-bandgap semiconductor device is opaque to light in a visible light wavelength range, from a wavelength of 360 nm to a wavelength of 830 nm.

### BACKGROUND OF THE INVENTION

1. Field of the Invention

The present invention relates to a wide-bandgap semiconductor device which can be easily manufactured and in which variation in device characteristics can be limited.

2. Background Art

In recent years, wide-bandgap semiconductor devices have come into increased use for energy saving or as a high-performance semiconductor device (see, for example, Japanese Patent Laid-Open No. 2005-64492), because they withstand a higher voltage, have higher efficiency and are capable of blue light emission and high-temperature operation in comparison with silicon or GaAs semiconductor devices.

### SUMMARY OF THE INVENTION

The substrates of conventional wide-bandgap semiconductor devices are transparent because they are made of GaN having a bandgap Eg=3.4 eV or SiC having a bandgap Eg=3.26 eV. Therefore, the substrate cannot be recognized in the wafer process. In an operation to adjust focus to the front surface in the process of inspecting wafers or assemblies, there is a possibility of making a determination error by erroneously adjusting focus to the back surface. Also, an SiN or SiO₂ protective film protecting the semiconductor surface is difficult to see and it is difficult to measure the film thickness.

In a case where the semiconductor device is used in an environment without shielding from light, external light permeates the substrate to cause variation in device characteristics. There is also a problem that light produced in an active region in the semiconductor permeates the substrate and is reflected in the substrate to cause variation in device characteristics on the same substrate.

In view of the above-described problems, an object of the present invention is to provide a wide-bandgap semiconductor device which can be easily manufactured and in which variation in device characteristics can be limited.

According to the present invention, a wide-bandgap semiconductor device includes: a semiconductor substrate made of a semiconductor material having bandgaps larger than 1.42 eV; a semiconductor layer on the semiconductor substrate and made of a semiconductor material having bandgaps larger than 1.42 eV; and an active region in the semiconductor layer and including a transistor, wherein the wide-bandgap semiconductor device is opaque to light in a visible range from a wavelength of 360 nm to a wavelength of 830 nm.

The present invention makes it possible to provide a wide-bandgap semiconductor device which can be easily manufactured and in which variation in device characteristics can be limited.

Other and further objects, features and advantages of the invention will appear more fully from the following description.

### BRIEF DESCRIPTION OF THE DRAWINGS

FIG. 1 is a top view of a wide-bandgap semiconductor device according to a first embodiment of the present invention.

FIG. 2 is a sectional view of the semiconductor device.

FIG. 3 is a sectional view of a wide-bandgap semiconductor device according to a second embodiment of the present invention.

FIG. 4 is a sectional view of a wide-bandgap semiconductor device according to a third embodiment of the present invention.

FIG. 5 is a top view of a first modified example of the wide-bandgap semiconductor device according to the third embodiment of the present invention.

FIG. 6 is a top view of a second modified example of the wide-bandgap semiconductor device according to the third embodiment of the present invention.

FIG. 7 is a top view of a third modified example of the wide-bandgap semiconductor device according to the third embodiment of the present invention.

FIG. 8 is a sectional view of a wide-bandgap semiconductor device according to a fourth embodiment of the present invention.

### DETAILED DESCRIPTION OF THE PREFERRED EMBODIMENTS

A wide-bandgap semiconductor device according to the embodiments of the present invention will be described with reference to the drawings. The same components will be denoted by the same symbols, and the repeated description thereof may be omitted.

### First Embodiment

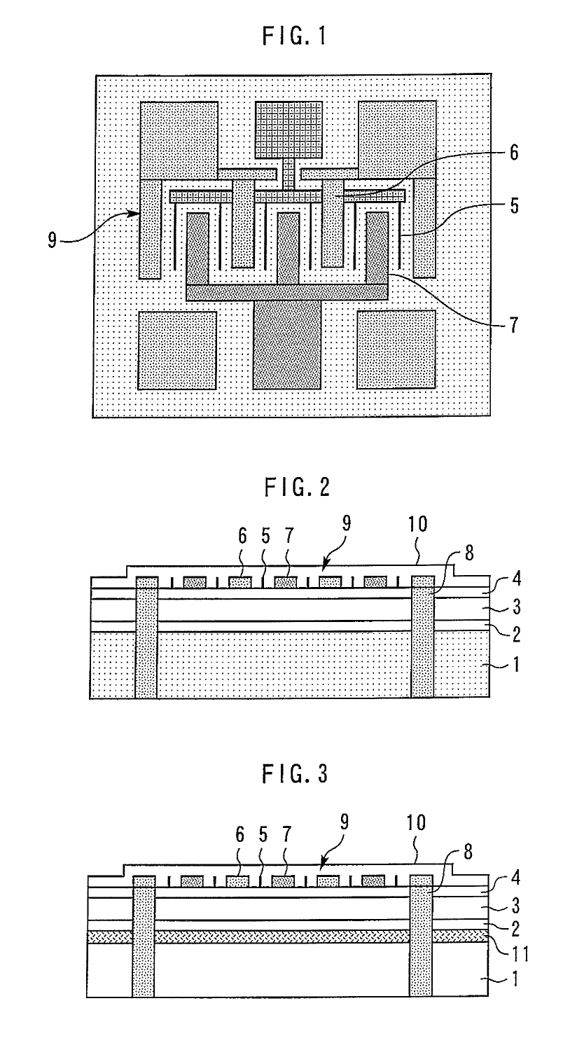

FIG. 1 is a top view of a wide-bandgap semiconductor device according to a first embodiment of the present invention. FIG. 2 is a sectional view of the semiconductor device. The device according to the present embodiment is not an optical device but an electronic device having an active region including a transistor.

An SiC substrate 1 has a thickness of about 100 to 500 μm. An AlN lattice buffer layer 2, a GaN channel layer 3 and an AlGaN electron supply layer 4 are provided in this order on the SiC substrate 1. The AlN lattice buffer layer 2 relieves a lattice mismatch between the SiC substrate 1 and the GaN channel layer 3. Two-dimensional electron gas is formed in the GaN channel layer 3. The AlGaN electron supply layer 4 forms a Schottky barrier and supplies electrons.

A gate electrode 5, a source electrode 6 and a drain electrode 7 are formed on the AlGaN electron supply layer 4. The source electrode 6 is electrically connected to the back surface of the SiC substrate 1 by a via 8 passing through the SiC substrate 1. Thus, an active region 9 including a transistor is provided in the semiconductor layers. To protect the active region 9, a protective film 10 formed of SiN or SiO₂, is provided on the AlGaN electron supply layer 4.

In the present embodiment, the SiC substrate 1 is colored by adding (being doped with) an optical impurity. As this impurity, a rare earth element such as europium (Eu) or a transition metal such as Fe and Cr, acting as a color center, is effective. Any other impurity may be used if it has no influence on device characteristics in terms of electrical resistance, dielectric permittivity, thermal conductivity, thermal expansion coefficient and crystallinity of the epilayer.

To color the SiC substrate 1 in an alternative way, lattice defects may be produced by applying radioactive rays to the SiC substrate 1. For example, a 10 MeV electron beam is applied at 10E16 to 10E18/cm²; 18 MeV protons are applied at 10E13 to 10E14/cm²; and neutrons are applied at 10E16 to 10E18/cm². Any other radioactive rays can be freely selected regardless of kinds of ray source such as a heavy particle source and gamma rays if they can cause lattice defects. Also, the dose can be freely selected by considering the transparency.

The SiC substrate 1 colored by the optical impurity or lattice defects absorbs light in the visible region from a wavelength of 360 nm to a wavelength of 830 nm, so that its transmittance is reduced to several percents or lower. Accordingly, the device in the present embodiment is opaque to light in the visible range.

It is thereby made possible to automatically recognize the substrate in the wafer process. Therefore, the wafer process can be caused to run automatically without modifying the conventional line and without adding a wafer recognition step. Also, because the region below the back surface of the device is made difficult to see, the occurrence of an error in focusing in the inspection process can be prevented. Moreover, since the protective film protecting the semiconductor surface is made easier to see, the accuracy with which the protective film is formed is improved. Manufacturing of the device is thus made easier.

Prevention of external light from entering the substrate can also be achieved even in the case of use in an environment without shielding from light. Prevention of light produced in the active region from permeating the substrate and being reflected in the substrate is also enabled, thus limiting variation in device characteristics.

### Second Embodiment

FIG. 3 is a sectional view of a wide-bandgap semiconductor device according to a second embodiment of the present invention. Instead of coloring of the SiC substrate 1 as in the first embodiment, a light absorbing layer 11 is provided between the SiC substrate 1 and the MN lattice buffer layer 2 in the present embodiment.

The light absorbing layer 11 is formed of a semiconductor material having bandgap narrower than those of the SiC substrate 1, the AlN lattice buffer layer 2, the GaN channel layer 3 and the AlGaN electron supply layer 4, and absorbs light in the visible region. As a material forming the light absorbing layer 11, a material lattice-matching the SiC substrate 1 and the like is preferred. Examples of such a material are InN, InAs, InGaN, GaAsN and Si. If a superlattice buffer layer is used, even a material having substantially different lattice constants can be used.

Since the light absorbing layer 11 absorbs light in the visible region, the device in the present embodiment is opaque to light in the visible region. Therefore the same effects as those in the first embodiment can also be obtained.

### Third Embodiment

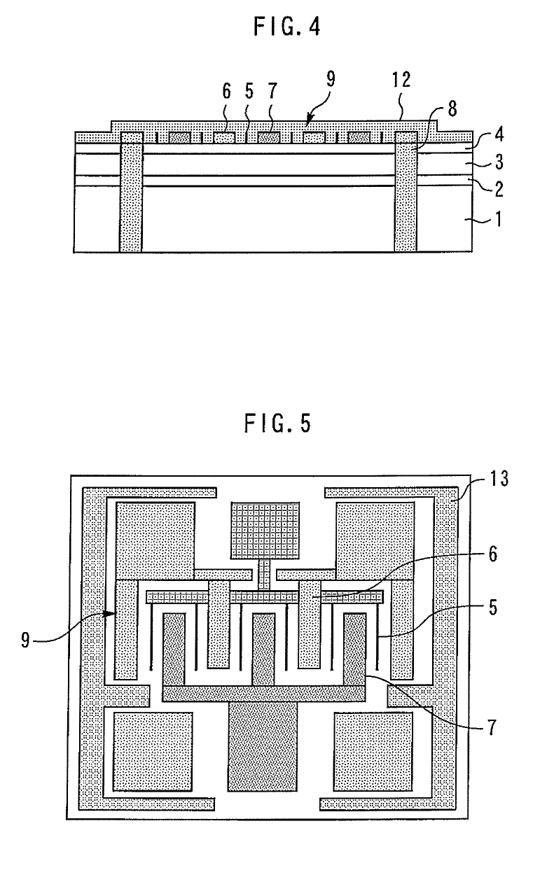

FIG. 4 is a sectional view of a wide-bandgap semiconductor device according to a third embodiment of the present invention. Instead of coloring of the SiC substrate 1 as in the first embodiment, a multilayer film 12 is provided as a protective film on the entire surface of the AlGaN electron supply layer 4 in the present embodiment.

The multilayer film 12 is formed by laminating a plurality of insulating films having different refractive indices, and absorbs light in the visible region. The material of the multilayer film 12 is, for example, ZnO, Al₂O₃, MgO, SiO₂, AlN, polyimide or benzo-cyclo-butene (BCB).

Ordinary protective films are transparent films such as SiN and SiO₂. Therefore ordinary devices are transparent to light in the visible region. On the other hand, in the present embodiment, the multilayer film 12 absorbs light in the visible region and the device in the present embodiment is opaque to light in the visible region. Thus, the same effects as those in the first embodiment can be obtained.

A single-layer film may be provided in place of the multilayer film 12 if it can absorb light in the visible region. However, the multilayer film 12 is capable of increasing the absorption coefficient with respect to light in the visible region higher and has a higher opaquing effect.

While the multilayer film 12 is formed on the entire device in the described embodiment, the arrangement may alternatively be such that the multilayer film 12 is formed only on space regions other than the active region 9 and wiring. In such a case, little portions of transparent SiC substrate 1 are seen but a major portion of the area is covered with the multilayer film 12, so that substantially the same effects can be obtained.

FIG. 5 is a top view of a first modified example of the wide-bandgap semiconductor device according to the third embodiment of the present invention. A metal film 13 formed of Au, Al, WSi or TaN, for example, is provided on regions other than the active region 9 instead of the above-described multilayer film 12. The metal film 13 may be formed by an added process. However, if the metal film 13 is formed simultaneously with other metal portions in the wafer process, the number of process steps can be reduced. Thus, on regions other than the active region 9, not a dielectric or an organic film but the metal film 13 can be used as a protective film. The regions on which the metal film 13 is formed are substantially completely nontransparent.

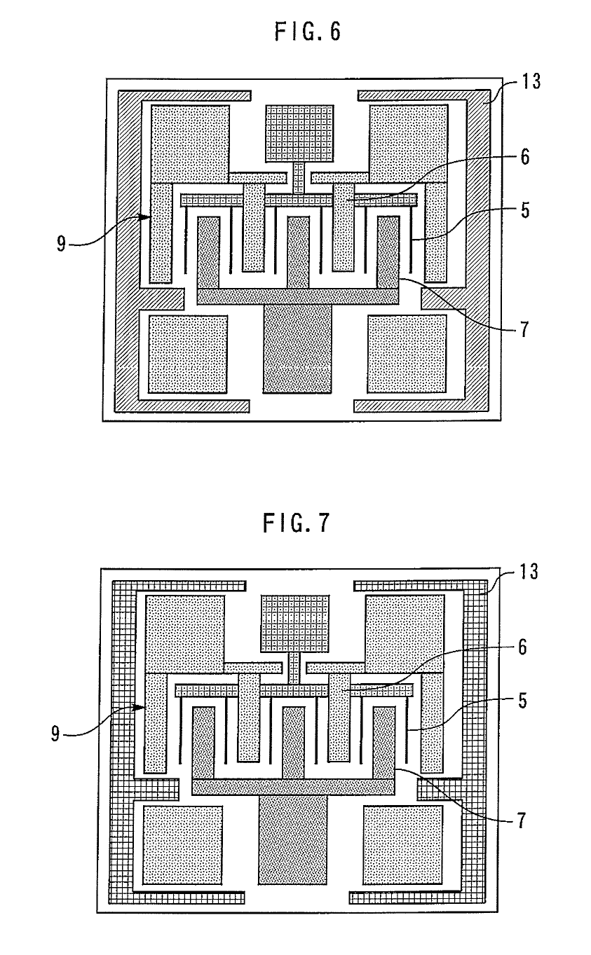

FIG. 6 is a top view of a second modified example of the wide-bandgap semiconductor device according to the third embodiment of the present invention. FIG. 7 is a top view of a third modified example of the wide-bandgap semiconductor device according to the third embodiment of the present invention. As shown in these figures, the metal film 13 may be formed in dot or lattice form. The metal film 13 formation area is reduced thereby. In this way, the influences of a parasitic capacitance and electromagnetic induction in the device can be limited.

### Fourth Embodiment

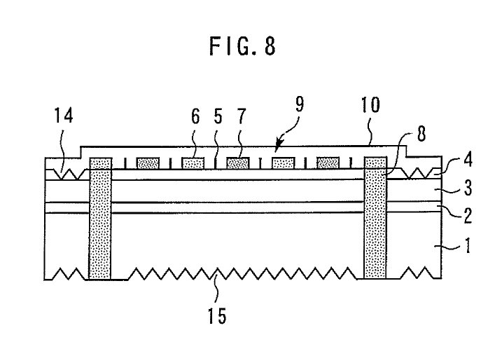

FIG. 8 is a sectional view of a wide-bandgap semiconductor device according to a fourth embodiment of the present invention. Instead of coloring of the SiC substrate 1 as in the first embodiment, projected/recessed structures 14 and 15 are provided in the present embodiment.

The projected/recessed structure 14 is provided in regions of the external surface of the AlGaN electron supply layer 4 other than the active region 9. Examples of a method of making the projected/recessed structure 14 are patterning and etching, anisotropic etching utilizing crystal anisotropy, and etching utilizing the speed of etching on dislocations as lattice defects.

The projected/recessed structure 15 is provided in the back surface of the SiC substrate 1. Examples of a method of making the projected/recessed structure 15 include a method of making surface roughness by sandblasting as well as the examples of the method of making the projected/recessed structure 14. A method of using irregularities produced at the time of cutting out the SiC substrate 1 from an ingot without performing any processing on them may alternatively be used.

Because the projected/recessed structures 14 and 15 absorb light in the visible region, the device according to the present embodiment is opaque to light in the visible region. Also, because the refractive index of the device is higher than that of air, light is slightly scattered at the substrate back surface, while total reflection occurs at the front surface, so that the device is apparently opaque due to light confinement effect. Therefore the region below the back surface of the device is difficult to see. As a result, the same effects as those in the first embodiment can be obtained.

The constituent materials of the SiC substrate 1, the AlN lattice buffer layer 2, the GaN channel layer 3 and the AlGaN electron supply layer 4 are not limited to these materials. Semiconductor materials having bandgaps larger than 1.42 eV of GaAs suffice. However, the thermal conductivity can be improved by using materials including SiC relative to that of ordinary Si devices. In this way, temperature degradation due to an increase in channel temperature can be prevented and an improvement in reliability can be achieved.

In each of the above-described embodiments, the device is made opaque to light in the visible range. However, the present invention is not limited to this. The device may be made opaque in an infrared region, in an ultraviolet region, or through a wide region from an infrared region to an ultraviolet region.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2011-186428, filed on Aug. 29, 2011, including specification, claims, drawings, and summary, on which the Convention priority of the present application is based, is incorporated herein by reference in its entirety.

1. A wide-bandgap semiconductor device comprising:
a semiconductor substrate made of a semiconductor material having a bandgap larger than 1.42 eV;
a semiconductor layer on the semiconductor substrate and made of a semiconductor material having a bandgap larger than 1.42 eV; and
an active region in the semiconductor layer and including a transistor, wherein the wide-bandgap semiconductor device is opaque to light in a visible light wavelength region from a wavelength of 360 nm to a wavelength of 830 nm.

2. The wide-bandgap semiconductor device according to claim 1, wherein the semiconductor substrate is colored by an optical impurity or a lattice defect and absorbs light in the visible light wavelength region.

3. The wide-bandgap semiconductor device according to claim 1, further comprising a light absorbing layer located between the semiconductor substrate and the semiconductor layer, made of a semiconductor material having a bandgap narrower than those of the semiconductor substrate and the semiconductor layer, and absorbing light in the visible light wavelength region.

4. The wide-bandgap semiconductor device according to claim 1, further comprising a protective film on the semiconductor substrate and absorbing light in the visible light wavelength region.

5. The wide-bandgap semiconductor device according to claim 4, wherein the protective film is located on a region other than the active region.

6. The wide-bandgap semiconductor device according to claim 4, wherein the protective film is formed by laminating a plurality of insulating films having different refractive indices.

7. The wide-bandgap semiconductor device according to claim 5, wherein the protective film is a metal film in dot or lattice form.

8. The wide-bandgap semiconductor device according to claim 1, wherein a projecting recessed structure is located on at least one of a front surface and a back surface of the semiconductor substrate, and the projecting recessed structure absorbs light in the visible light wavelength region.
